(19) United States
(12) Patent Application Publication
(10) Pub. No.: US 2026/0269562 A1
(43) Pub. Date: Sep. 10, 2026

(54) SEMICONDUCTOR OPTICAL INTEGRATED DEVICE AND SEMICONDUCTOR OPTICAL APPARATUS

(71) Applicant: Lumentum Operations LLC, San Jose, CA (US)

(72) Inventors: Takanori SUZUKI, Tokyo (JP); Shuhei OHNO, Sagamihara (JP); Ryosuke HATAI, Sagamihara (JP)

(21) Appl. No.: 19/284,871

(22) Filed: Jul. 30, 2025

(30) Foreign Application Priority Data
Mar. 7, 2025 (JP) 2025036511
Apr. 25, 2025 (JP) 2025073467

(51) Int. Cl. H01S 5/026; H01S 5/02325; H01S 5/02345; H01S 5/227

(52) U.S. Cl. CPC H01S 5/0265; H01S 5/02325; H01S 5/02345; H01S 5/227

(57) ABSTRACT

Provided is a semiconductor optical integrated device including: a first optical function section; an isolation section; and a second optical function section, the first optical function section, the isolation section, and the second optical function section being aligned in a first direction in the stated order, the isolation section including a first high-resistance portion which is a semiconductor and a second high-resistance portion which is a semiconductor different from the first high-resistance portion, the first high-resistance portion and the second high-resistance portion being alternatingly arranged in the first direction, wherein the semiconductor optical integrated device includes semiconductor boundaries, the number of which is four or more, and each of which is a boundary between the first high-resistance portion and the second high-resistance portion.

### CROSS-REFERENCE TO RELATED APPLICATION

This Patent Application claims priority to Japan Patent Application No. JP2025-073467, filed on Apr. 25, 2025, and Japan Patent Application No. JP 2025-036511, filed on Mar. 7, 2025. The disclosure of the prior Applications are considered part of and are incorporated by reference into this Patent Application.

### TECHNICAL FIELD

The present invention relates to a semiconductor optical integrated device and a semiconductor optical apparatus.

### BACKGROUND

A semiconductor optical integrated device in which a plurality of optical function sections are integrated on a single semiconductor substrate is a type of semiconductor optical apparatuses used for optical communication. In some cases, a modulator integrated laser device includes a laser section for emitting continuous light, a modulator section for converting the output light of the laser section into a modulated optical signal, and a separation section for connecting the laser section and the modulator section to each other that are integrated on a substrate

### SUMMARY

Technologies exist that address when a voltage applied to a modulator section affects operation of a laser section. Specifically, in a configuration, isolation resistance can be observed between a laser section and a modulator section by reducing a sectional area of a lower cladding layer of a separation section which connects a lower cladding layer of the modulator section and a lower cladding layer of the laser section to each other. The lower cladding layers are an n-type semiconductor layer common to the laser section, the modulator section, and the separation section.

With an increase in modulation frequency of an electrical signal input to the modulator section, reducing the sectional area of the lower cladding layer of the separation section alone is not enough to obtain sufficient isolation resistance in some cases.

Some implementations described herein include a semiconductor optical integrated device in which electrical crosstalk between two optical function sections is reduced, and a semiconductor optical apparatus including the semiconductor optical integrated device.

In some implementations, there is provided a semiconductor optical integrated device that includes: a first optical function section; an isolation section; and a second optical function section, the first optical function section, the isolation section, and the second optical function section being aligned in a first direction in the stated order, the isolation section including a first high-resistance portion which is a semiconductor and a second high-resistance portion which is a semiconductor different from the first high-resistance portion, the first high-resistance portion and the second high-resistance portion being alternatingly arranged in the first direction, wherein the semiconductor optical integrated device includes semiconductor boundaries, the number of which is four or more, and each of which is a boundary between the first high-resistance portion and the second high-resistance portion.

### BRIEF DESCRIPTION OF THE DRAWINGS

FIG. 1 is a top view of a semiconductor optical integrated device according to a first example implementation of the present invention.

FIG. 2 is a sectional view taken along the line II-II of the semiconductor optical integrated device illustrated in FIG. 1.

FIG. 3 is a sectional view taken along the line III-III of the semiconductor optical integrated device illustrated in FIG. 1.

FIG. 4 is a sectional view taken along the line A-A of the semiconductor optical integrated device illustrated in FIG. 1.

FIG. 5 is a sectional view taken along the line B-B of the semiconductor optical integrated device illustrated in FIG. 1.

FIG. 6 is a top view of a semiconductor optical integrated device according to a second example implementation of the present invention.

FIG. 7 is a sectional view taken along the line A-A of the semiconductor optical integrated device illustrated in FIG. 6.

FIG. 8 is a sectional view taken along a line of a semiconductor optical integrated device according to a third example implementation of the present invention.

FIG. 9 is a sectional view taken along a line of the semiconductor optical integrated device according to the third example implementation.

FIG. 10 is a top view of a semiconductor optical integrated device according to a fourth example implementation of the present invention.

FIG. 11 is a sectional view taken along the line A-A of the semiconductor optical integrated device illustrated in FIG. 10.

FIG. 12 is a top view of a semiconductor optical integrated device according to a modification example of the fourth example implementation.

FIG. 13 is a sectional view taken along the line A-A of the semiconductor optical integrated device illustrated in FIG. 12.

FIG. 14 is a top view of a semiconductor optical apparatus according to a fifth example implementation of the present invention.

### DETAILED DESCRIPTION

A specific and detailed description is given below on embodiments of the present invention with reference to the drawings. Members denoted by the same reference symbol throughout the drawings have the same or an equivalent function, and a repetitive description on the members is omitted. Note that sizes of graphics are not always to scale.

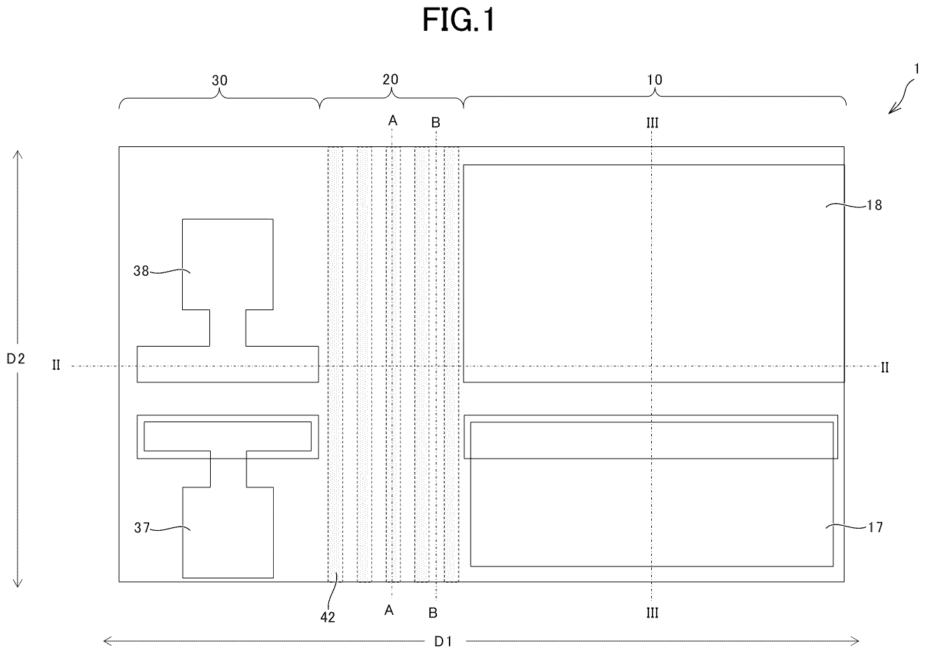

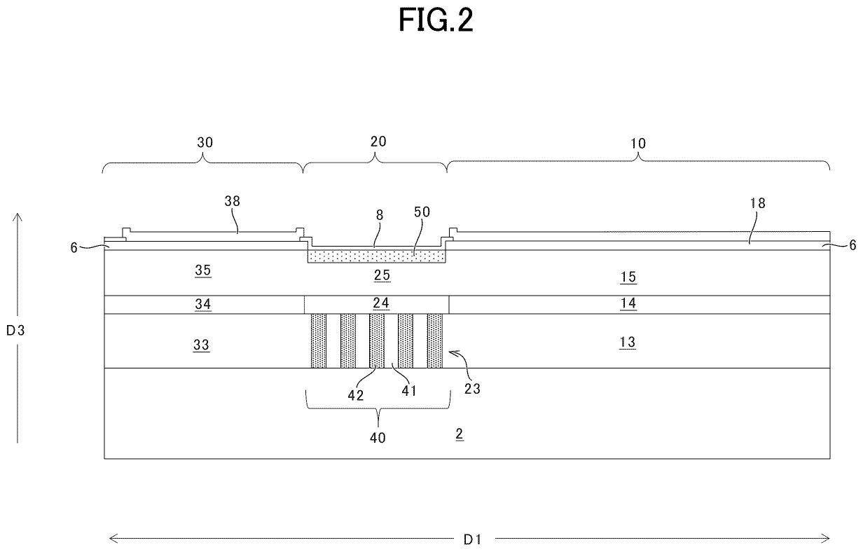

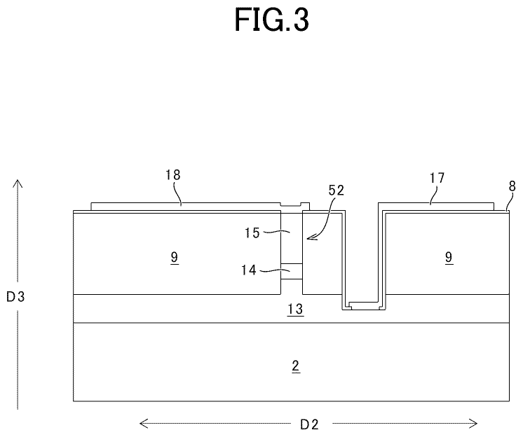

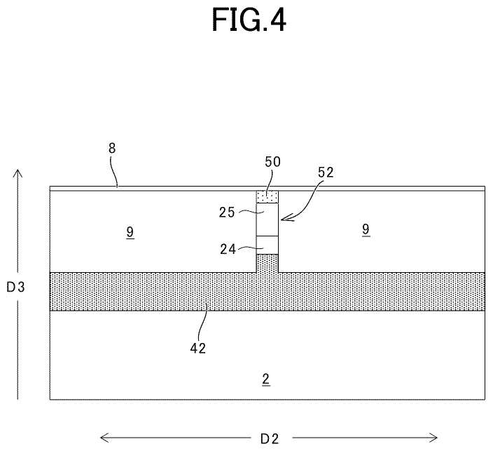

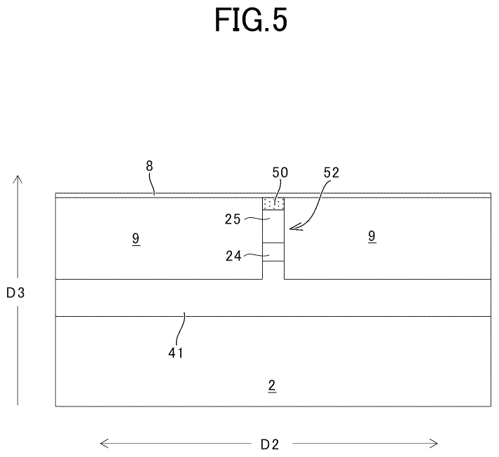

FIG. 1 is a top view of a semiconductor optical integrated device 1 according to a first example implementation of the present invention. FIG. 2 is a sectional view for schematically illustrating a II-II section of FIG. 1. FIG. 3 is a sectional view for schematically illustrating a III-III section of FIG. 1. FIG. 4 is a sectional view for schematically illustrating an A-A section of FIG. 1. FIG. 5 is a sectional view for schematically illustrating a B-B section of FIG. 1.

In the semiconductor optical integrated device 1, a plurality of optical function sections are integrated unitarily on a substrate 2. In the first example implementation, two optical function sections are integrated on the substrate 2. The two optical function sections may be a laser section 10 (a first optical function section) that outputs continuous light and a modulation section 30 (a second optical function section) that converts the output light of the laser section 10 into a modulated optical signal. A waveguide section 20 (an isolation section) that establishes optical connection between the laser section 10 and the modulation section 30 may be further integrated on the substrate 2. A direction in which the laser section 10, the waveguide section 20, and the modulation section 30 are aligned is a first direction D1. The first direction D1 may be an optical axis direction. The substrate 2 may be a semi-insulating semiconductor substrate.

The semiconductor optical integrated device 1 may include a mesa structure 52. The mesa structure 52 extends in the first direction D1 across the laser section 10, the waveguide section 20, and the modulation section 30. In a second direction D2 perpendicular to the first direction D1 and to a normal line direction of the substrate 2 (a third direction D3), a buried layer 9 of a semiconductor may be placed on each side of the mesa structure.

The laser section 10 may include a semiconductor multilayer in which a first lower semiconductor layer 13 of a first conductivity type, a first core layer 14, a first upper semiconductor layer 15 of a second conductivity type, and a contact layer 6 of the second conductivity type are grown in the stated order. In the first example implementation, the first conductivity type is an n-type, and the second conductivity type is a p-type, but the types may be reversed. The first lower semiconductor layer 13 may include at least a cladding layer, and may be a multilayer. The first core layer 14 may include at least an active layer. The first upper semiconductor layer 15 may include at least a cladding layer, and may be a multilayer. The contact layer 6 may be a layer that electrically and physically connects to a second laser-section electrode 18 described later. The contact layer 6 may be omitted. The mesa structure 52 may include a part of the first lower semiconductor layer 13, the first core layer 14, the first upper semiconductor layer 15, and the contact layer 6. The laser section 10 may include a first laser-section electrode 17 and the second laser-section electrode 18 for establishing electrical connection. The first laser-section electrode 17 electrically and physically connects to the first lower semiconductor layer 13 in a bottom portion of a groove portion formed in a part of the buried layer 9. The second laser-section electrode 18 electrically and physically connects to the contact layer 6 on a top surface of the mesa structure 52. An insulating film 8 may be placed on a top surface of the buried layer 9, a part of a bottom surface of the groove portion, side surfaces of the groove portion, and a part of a top surface of the contact layer 6. No insulating film 8 may be placed in a portion in which the first laser-section electrode 17 and the first lower semiconductor layer 13 may be in contact with each other, and a portion in which the second laser-section electrode 18 and the contact layer 6 may be in contact with each other. The laser section 10 generates continuous light via application of a direct-current voltage (injection of a direct current) between the first laser-section electrode 17 and the second laser-section electrode 18. The laser section 10 may include a diffraction grating layer.

The modulation section 30 may include a semiconductor multilayer in which a third lower semiconductor layer 33 of the first conductivity type, a third core layer 34, a third upper semiconductor layer 35 of the second conductivity type, and the contact layer 6 of the second conductivity type are grown in the stated order. The third lower semiconductor layer 33 may include at least a cladding layer, and may be a multilayer. The third core layer 34 may include at least an absorption layer. The third upper semiconductor layer 35 may include at least a cladding layer, and may be a multilayer. The contact layer 6 may be a layer that electrically and physically connects to a second modulation-section electrode 38 described later. The contact layer 6 may be omitted. The modulation section 30 may include a first modulation-section electrode 37 and the second modulation-section electrode 38 for establishing electrical connection. A sectional structure of the modulation section 30 on a cutting plane along which the modulation section 30 is cut perpendicularly to the first direction D1 is substantially the same as a sectional structure of the laser section 10 on the same cutting plane. That is, the mesa structure 52 includes a part of the third lower semiconductor layer 33, the third core layer 34, the third upper semiconductor layer 35, and the contact layer 6. The first modulation-section electrode 37 electrically and physically connects to the third lower semiconductor layer 33 in a bottom portion of a groove portion formed in a part of the buried layer 9. The second modulation-section electrode 38 electrically and physically connects to the contact layer 6 on the top surface of the mesa structure 52. The insulating film 8 may be placed on the top surface of the buried layer 9, a part of the bottom surface of the groove portion, the side surfaces of the groove portion, and a part of the top surface of the contact layer 6. No insulating film 8 may be placed in a portion in which the first modulation-section electrode 37 and the third lower semiconductor layer 33 may be in contact with each other, and a portion in which the second modulation-section electrode 38 and the contact layer 6 may be in contact with each other. The modulation section 30 converts the output light of the laser section 10 into continuous light that may be a modulated optical signal in accordance with high-frequency electrical signals applied between two electrodes. The modulation section 30 here is an electro-absorption modulator. However, the modulation section 30 is not limited thereto, and may be an MZ modulator.

The waveguide section 20 may include a semiconductor multilayer in which a second lower semiconductor layer 23, a second core layer 24, and a second upper semiconductor layer 25 of the second conductivity type may be grown in the stated order. Details of the second lower semiconductor layer 23 are described later. In the following, the first lower semiconductor layer 13, the second lower semiconductor layer 23, and the third lower semiconductor layer 33 are collectively referred to as “lower semiconductor layers” in some cases. The second core layer 24 may include a bulk semiconductor layer for transmitting, without absorbing the output light from the laser section 10, the light to the modulation section 30. The third upper semiconductor layer 35 may include at least a cladding layer, and may be a multilayer. In the first example implementation, the first upper semiconductor layer 15, the second upper semiconductor layer 25, and the third upper semiconductor layer 35 may be a unitarily formed layer. However, the first upper semiconductor layer 15, the second upper semiconductor layer 25, and the third upper semiconductor layer 35 may be bodies separate from one another. In the following description, the first upper semiconductor layer 15, the second upper semiconductor layer 25, and the third upper semiconductor layer 35 may be collectively referred to as “upper semiconductor layers” in some cases. The mesa structure 52 may include a part of the second lower semiconductor layer 23, the second core layer 24, and the second upper semiconductor layer 25. A border between the laser section 10 and the waveguide section 20 may be defined by a boundary between the first core layer 14 and the second core layer 24, and a border between the waveguide section 20 and the modulation section 30 may be defined by a boundary between the second core layer 24 and the third core layer 34.

The waveguide section 20 may have a high-resistance portion 40 in the second lower semiconductor layer 23. In the high-resistance portion 40, a plurality of at least two different types of semiconductor portions (a first high-resistance portion 41 and a second high-resistance portion 42) may be alternatingly arranged in the first direction D1. The first high-resistance portion 41 and the second high-resistance portion 42 here differ from each other in at least one of dopant, material that serves as a base, or carrier concentration. For example, when the material that serves as a base is InP, an undoped InP portion, an n-type InP portion, a p-type InP portion, and a semi-insulating InP portion may be semiconductor portions different from one another. The undoped semiconductor portion may be a semiconductor in which a material that serves as a base is not intentionally doped with any dopant. The n-type InP portion may be InP doped with, for example, Si. Similarly, the p-type InP portion may be InP doped with Zn, and the semi-insulating InP portion may be InP doped with Fe. Those dopants may be merely an example, and other dopants may be used. Each of the semiconductor portions may be doped with a plurality of dopants. For example, the n-type InP portion doped with Si may be doped with Zn until the p-type conductivity may be acquired, to thereby form a p-type InP portion. In this case, the n-type InP portion doped with Si alone and the p-type InP portion doped with Si and Zn both may be semiconductor portions different from each other. An example of the case in which different materials are used as bases is a case in which the first high-resistance portion 41 is InP and the second high-resistance portion 42 is not InP. A case in which the first high-resistance portion 41 may be InP and the second high-resistance portion 42 may be InGaAsP or the like may be given as an example. When different materials may be used as bases, the first high-resistance portion 41 and the second high-resistance portion 42 may be doped with the same dopant or different dopants. The case in which different carrier concentrations are used is a case in which the carrier concentration of the first high-resistance portion 41 and the carrier concentration of the second high-resistance portion 42 differ from each other. The carrier concentrations may be desired to differ from each other by one digit or more. It goes without saying that the different types of semiconductor portions may differ from each other in, in addition to carrier concentration, dopant and material used as a base.

In the first example implementation, a plurality of high-resistance portions each of which is one of the first high-resistance portion 41 and the second high-resistance portion 42 are alternatingly arranged in the first direction D1. The terms “first high-resistance portion 41” and “second high-resistance portion 42” do not always mean that those portions themselves have high resistance, and are simply address terms for components that form the high-resistance portion 40. The first high-resistance portion 41 and the second high-resistance portion 42 may be semiconductor layers different from each other. For example, the first high-resistance portion 41 is n-type InP, as are parts of the second lower semiconductor layer 23 other than the second high-resistance portion 42. The second high-resistance portion 42 may be p-type InP doped with, for example, Zn. In the first example implementation, the first lower semiconductor layer 13, the second lower semiconductor layer 23, and the third lower semiconductor layer 33 may be a unitarily formed layer. In the waveguide section 20, a plurality of high-resistance portions each of which is one of the first high-resistance portion 41 (n-type InP) and the second high-resistance portion 42 (p-type InP) may be alternatingly arranged in the first direction. The high-resistance portion 40 formed from the first high-resistance portion 41 and the second high-resistance portion 42 extends in a straight line along the second direction D2, and reaches both side surfaces of the semiconductor optical integrated device 1. In FIG. 1, the second high-resistance portion 42 may be indicated by the broken line in a perspective view for an explanatory purpose.

A direct current may be injected into (a direct-current voltage may be applied to) the electrodes of the laser section 10. In contrast, high-frequency electrical signals may be applied to the electrodes of the modulation section 30. The laser section 10 and the modulation section 30 may be integrated on the substrate 2, and the lower semiconductor layers and the upper semiconductor layers may be each a unitary layer continuous from the laser section 10 to the modulation section 30. Accordingly, there may be a case in which crosstalk of electrical signals between two optical function sections (the laser section 10 and the modulation section 30) occurs to degrade characteristics of the semiconductor optical integrated device 1. In the first example implementation, the high-resistance portion 40 may be placed to increase isolation resistance between the two optical function sections and thereby reduce crosstalk. The degradation of characteristics of the semiconductor optical integrated device 1 can thus be prevented. In the high-resistance portion 40, the first high-resistance portion 41 and the second high-resistance portion 42 may be alternatingly arranged in the first direction. A semiconductor boundary may be formed between the first high-resistance portion 41 and the second high-resistance portion 42. For example, a plurality of pn boundaries (ten pn boundaries in the first example implementation) may be formed between the laser section 10 and the modulation section 30 because the first high-resistance portion 41 is an n-type layer and the second high-resistance portion 42 is a p-type layer in the first example implementation. Energy barriers of the pn boundaries hinder a flow of carriers. As the number of pn boundaries which form the energy barriers becomes higher, the flow of carriers may be more hindered, with the result that electrical crosstalk between the laser section 10 and the modulation section 30 may be reduced. The semiconductor boundary placed here may be viewed in a direction that may be parallel to a front surface of the substrate 2 and that runs in the first direction D1.

In the first example implementation, the first high-resistance portion 41 may be n-type InP, as may be parts of the second lower semiconductor layer 23 other than the second high-resistance portion 42, but is not limited thereto. The first high-resistance portion 41 may be p-type InP. The first high-resistance portion 41 and the second high-resistance portion 42 are not limited to the n-type and the p-type, respectively, and may be undoped portions or semi-insulating portions as described above. For example, even when one of the first high-resistance portion 41 and the second high-resistance portion 42 is an undoped portion or a semi-insulating portion, an energy barrier is formed and the flow of carriers is accordingly suppressed, with the result that electrical crosstalk is reduced. Further, an undoped portion and a semi-insulating portion may be high in electrical resistivity themselves, and can accordingly reduce electrical crosstalk more. For that reason, when the high-resistance portion 40 is formed from just two portions that are an undoped portion and a semi-insulating portion, the same effect as the effect of the first example implementation may be obtained.

It is not required that every first high-resistance portion 41 among the plurality of high-resistance portions be the same semiconductor portion. For example, an n-type portion (the first high-resistance portion 41), a p-type portion (the second high-resistance portion 42), an undoped portion (the first high-resistance portion 41), and a p-type portion (the second high-resistance portion 42) may be arranged side by side in the first direction D1. This applies to the second high-resistance portion 42 as well. The material that is the base of the first high-resistance portion 41 and the material that is the base of the second high-resistance portion 42 are not always required to be the same as each other, but are desired to be the same as each other from the viewpoints of manufacturability and crystallinity.

In order to suppress electrical crosstalk, the second lower semiconductor layer 23 is desired to include at least four semiconductor boundaries each of which is a boundary between the first high-resistance portion 41 and the second high-resistance portion 42, between the laser section 10 (the first optical function section) and the modulation section 30 (the second optical function section). More desirably, the second lower semiconductor layer 23 may include six or more semiconductor boundaries.

In the first example implementation, the first upper semiconductor layer 15, the second upper semiconductor layer 25, and the third upper semiconductor layer 35 may be a unitarily formed layer as well. Accordingly, electrical crosstalk may occur also above the first core layer 14, above the second core layer 24, and above the third core layer 34. However, the upper semiconductor layers may be included in the mesa structure 52, and a sectional area of the upper semiconductor layers may be very small compared to the lower semiconductor layers. That is, compared to the lower semiconductor layers, electrical resistance of the upper semiconductor layers may be high and electrical crosstalk in the upper semiconductor layers may be accordingly small. The contact layer 6 which may have high conductivity may not be placed in the waveguide section 20. In order to further reduce electrical crosstalk, the waveguide section 20 may include an upper high-resistance portion 50 in the first example implementation. The upper high-resistance portion 50 may be a portion of the second upper semiconductor layer 25 that may be given high resistance by being injected with protons. The upper semiconductor layers may include a plurality of high-resistance portions each of which may be one of the first high-resistance portion 41 and the second high-resistance portion 42 similar to those of the high-resistance portion 40. The second upper semiconductor layer 25 may have resistance raised by giving the second upper semiconductor layer 25 a thickness thinner than a thickness of each of the first upper semiconductor layer 15 and the third upper semiconductor layer 35.

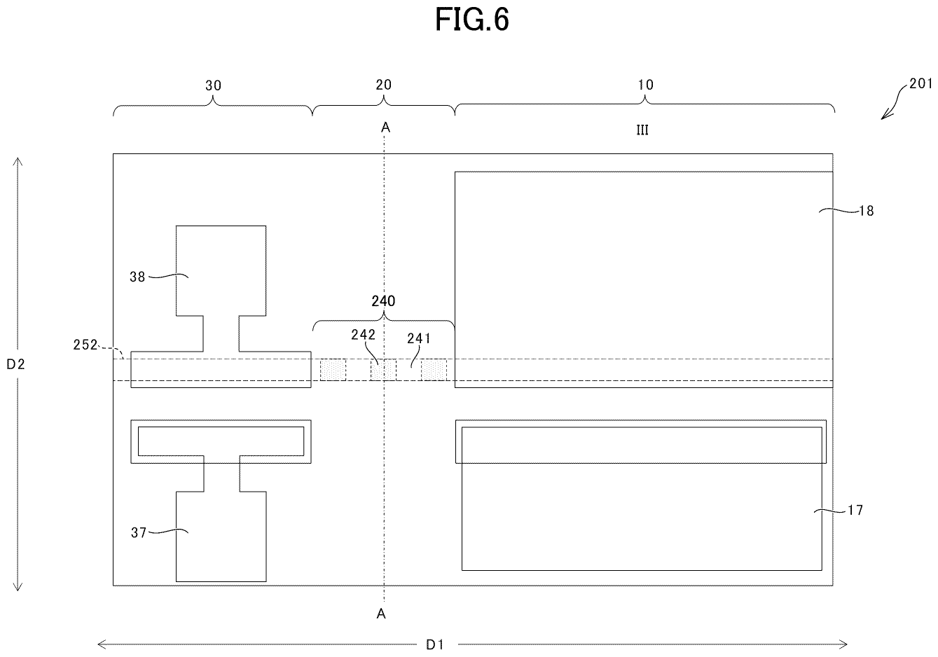

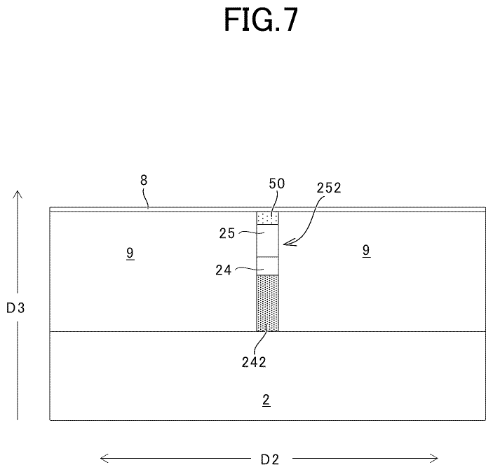

FIG. 6 is a top view of a semiconductor optical integrated device 201 according to a second example implementation of the present invention. FIG. 7 is a sectional view for schematically illustrating an A-A section of FIG. 6.

A difference of the semiconductor optical integrated device 201 according to the second example implementation from the semiconductor optical integrated device 1 according to the first example implementation is that a high-resistance portion 240 may be placed only inside a mesa structure 252. In FIG. 6, a boundary between a top surface of the mesa structure 252 and the buried layer 9 may be indicated by the broken line. A second high-resistance portion 242 may be also indicated by the broken line in a perspective view as in FIG. 1. In the second example implementation, the second lower semiconductor layer 23 is placed only inside the mesa structure 252. Although not shown, the first lower semiconductor layer 13 of the laser section 10 and the third lower semiconductor layer 33 of the modulation section 30 may be placed so as to spread wide on the substrate 2. The sectional structure of the laser section 10 on the cutting plane along which the laser section 10 is cut perpendicularly to the first direction D1 may be the same as a structure illustrated in FIG. 3. The second lower semiconductor layer 23 may include the high-resistance portion 240. As in the first example implementation, a first high-resistance portion 241 and the second high-resistance portion 242 may be alternatingly arranged in the high-resistance portion 240. The first high-resistance portion 241 and the second high-resistance portion 242 may be semiconductors different from each other. The second lower semiconductor layer 23 here may include six semiconductor boundaries between the laser section 10 and the modulation section 30. The first high-resistance portion 241 and the second high-resistance portion 242 each may have the same width as a width of the mesa structure 252.

In the second example implementation, a width of the second lower semiconductor layer 23 in the second direction D2 is narrower than in the first example implementation. For that reason, resistance of the second lower semiconductor layer 23 may be high in a suppositional case in which the second lower semiconductor layer 23 does not include the high-resistance portion 240. Accordingly, even with the smaller number of semiconductor boundaries than in the first example implementation, electrical crosstalk may be reduced satisfactorily in the second example implementation.

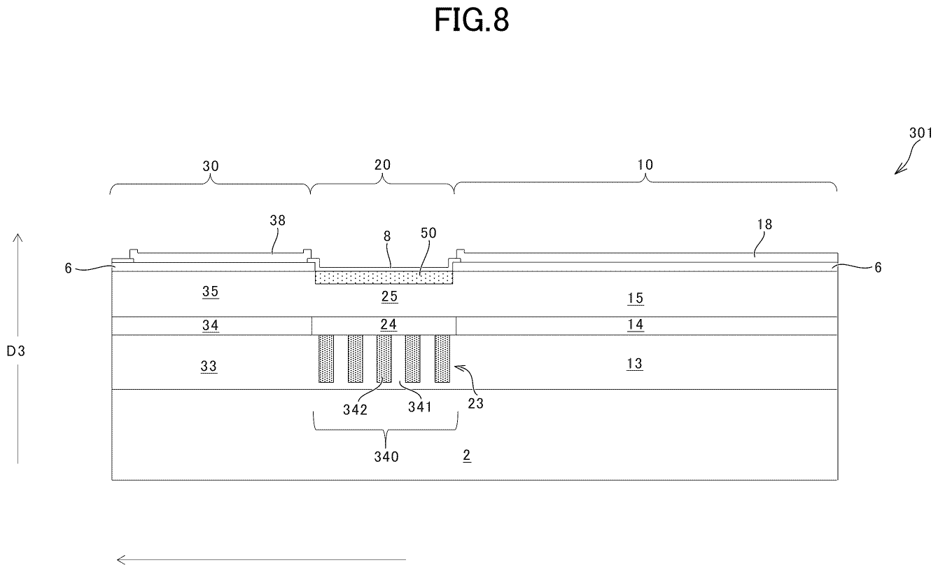

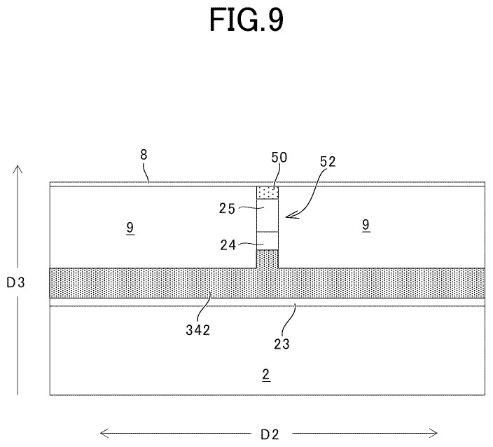

FIG. 8 is a sectional view taken along a direction of an optical axis of a semiconductor optical integrated device 301 according to a third example implementation of the present invention, and is a sectional view corresponding to FIG. 2. FIG. 9 is a sectional view taken along the second direction D2 of the semiconductor optical integrated device 301 according to the third example implementation, and is a sectional view corresponding to FIG. 4. A difference from the first example implementation is a structure of a high-resistance portion 340.

The high-resistance portion 340 may include a first high-resistance portion 341 and a second high-resistance portion 342. In the third example implementation, in the third direction D3, not all parts of the second lower semiconductor layer 23 have the second high-resistance portion 342 placed therein. Specifically, the second high-resistance portion 342 extends from an upper edge of the second lower semiconductor layer 23 downward and does not reach a lower edge of the second lower semiconductor layer 23. When the second lower semiconductor layer 23 extends from the laser section 10 to the modulation section 30 below a bottom surface of the second high-resistance portion 342, electrical crosstalk may occur. However, electrical isolation may be secured at a level that may be satisfactory in practice when the high-resistance portion 340 takes up an 80% or more region of the second lower semiconductor layer 23.

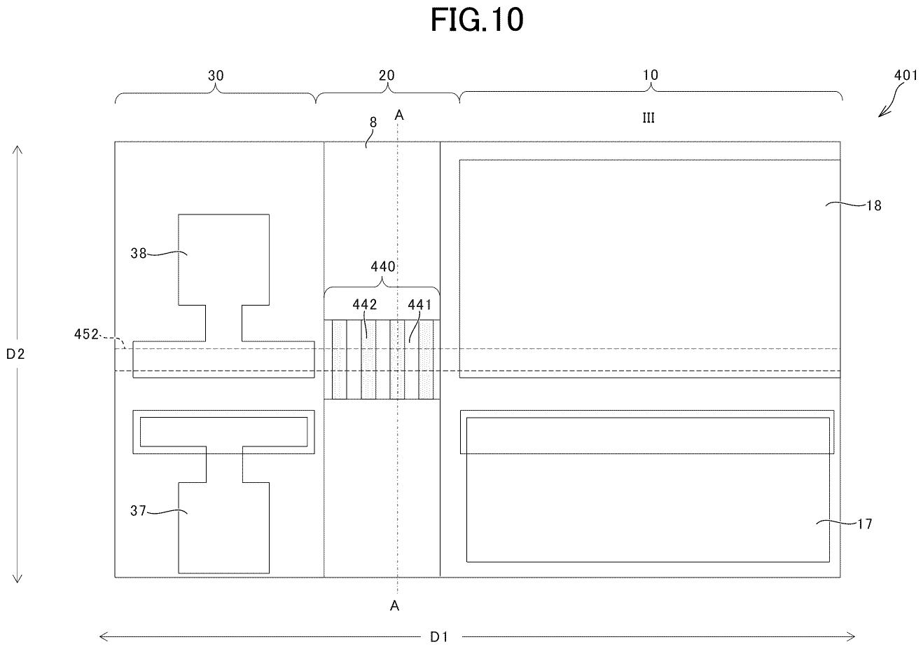

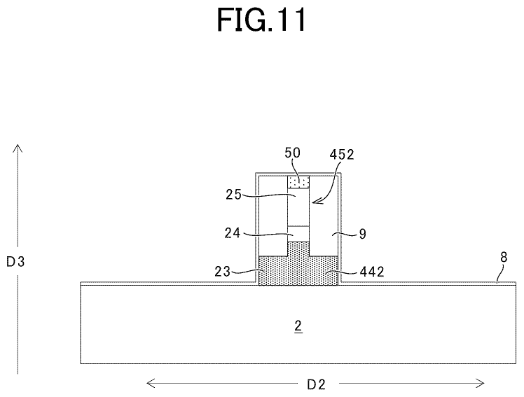

FIG. 10 is a top view of a semiconductor optical integrated device 401 according to a fourth example implementation of the present invention. FIG. 11 is a sectional view for schematically illustrating an A-A section of FIG. 10.

In the waveguide section 20, the buried layer 9 may be placed so as to fall short of side edges of the semiconductor optical integrated device 401 in the second direction D2. Although not shown, in the laser section 10 and the modulation section 30, the buried layer 9 may be placed so as to reach the side edges of the semiconductor optical integrated device 401 in the second direction D2. As in the second example implementation, the second lower semiconductor layer 23 may be narrower in width than the first lower semiconductor layer 13 and the third lower semiconductor layer 33 in the second direction D2. However, the width of the second lower semiconductor layer 23 may be wider than a width of a mesa structure 452. The sectional structure of the laser section 10 in the fourth example implementation may be the same as the structure illustrated in FIG. 3.

The second lower semiconductor layer 23 includes a high-resistance portion 440. In the high-resistance portion 440, a first high-resistance portion 441 and a second high-resistance portion 442 may be alternatingly arranged in the first direction D1 as in the other embodiments. The first high-resistance portion 441 and the second high-resistance portion 442 may be semiconductors different from each other. The second high-resistance portion 442 may be placed in all parts of the second lower semiconductor layer 23 in the second direction D2. In other words, two side edges of the second high-resistance portion 442 reach two side edges of the second lower semiconductor layer 23. The second high-resistance portion 442 may be designed so that only one side edge of the second high-resistance portion 442 reaches the corresponding one side edge of the second lower semiconductor layer 23.

The buried layer 9 may be formed from a semi-insulating semiconductor layer, or from a multilayer structure including a p-type semiconductor layer and an n-type semiconductor layer. The buried layer 9 may be accordingly higher in resistivity than a semiconductor layer having a conductivity type (for example, the lower semiconductor layers and the upper semiconductor layers). However, being placed across the laser section 10, the waveguide section 20, and the modulation section 30, the buried layer 9 may cause electrical crosstalk. In the fourth example implementation, electrical crosstalk may be further reduced by giving a narrow width in the second direction D2 to the buried layer 9 in the waveguide section 20.

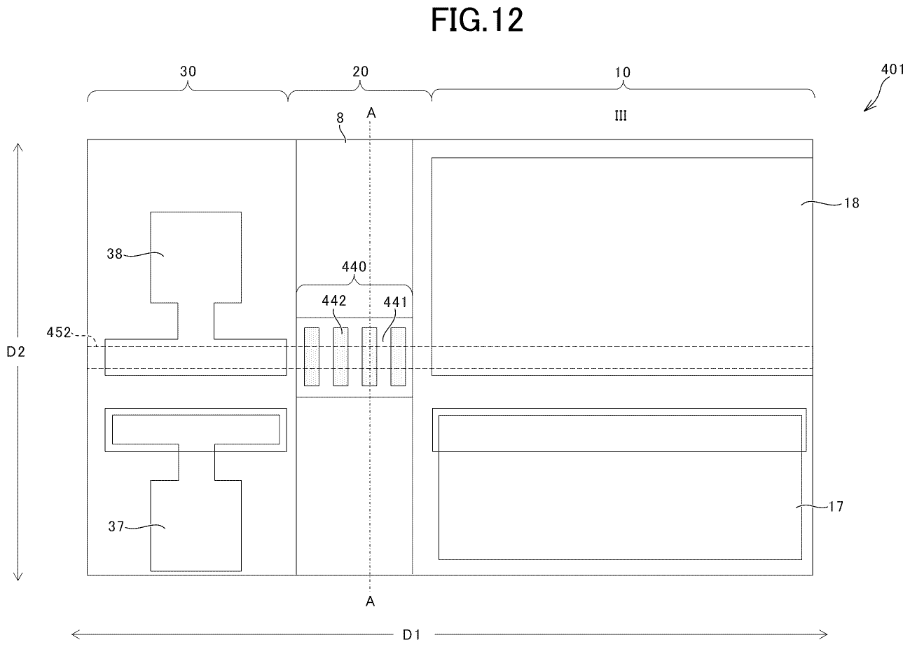

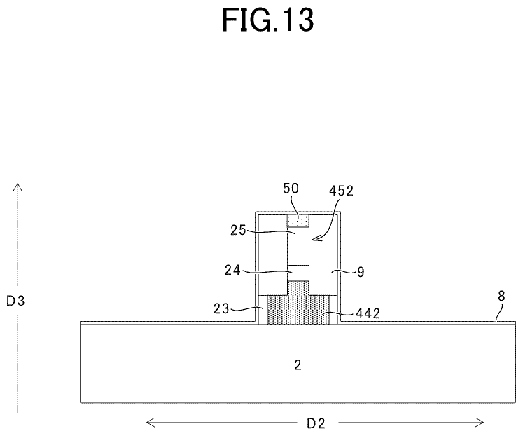

FIG. 12 is a top view of the semiconductor optical integrated device 401 according to a modification example of the fourth example implementation. FIG. 13 is a sectional view for schematically illustrating an A-A section of FIG. 12.

A difference of this modification example from the fourth example implementation is that not all parts of the second lower semiconductor layer 23 in the second direction D2 may have the second high-resistance portion 442 placed therein. The two side edges of the second high-resistance portion 442 fall short of the two side edges of the second lower semiconductor layer 23. The second high-resistance portion 442 may be designed so that only one side edge of the second high-resistance portion 442 falls short of the corresponding one side edge of the second lower semiconductor layer 23. The high-resistance portion 440 overlaps with the mesa structure 452 in plan view. As described in the third example implementation, in the third direction D3 as well, the high-resistance portion 440 is not required to be placed in all parts of the second lower semiconductor layer 23. Further, in both of the second direction D2 and the third direction D3, the high-resistance portion 440 is not required to be placed in all parts of the second lower semiconductor layer 23. That is, in both of the second direction D2 and the third direction D3, the high-resistance portion 440 may be designed so that at least one side edge of the high-resistance portion 440 falls short of at least one side edge of the second lower semiconductor layer 23. The high-resistance portion 440 may be desired to take up an 80% or more region of the second lower semiconductor layer 23.

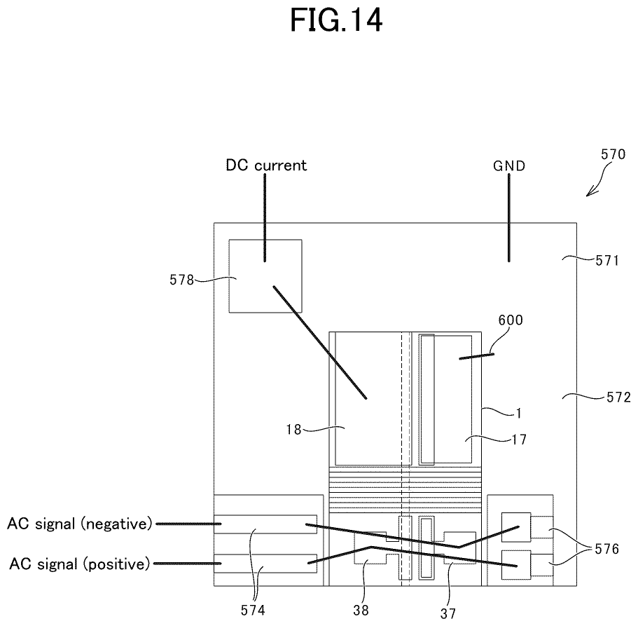

FIG. 14 is a top view of a semiconductor optical apparatus 570 according to a fifth example implementation of the present invention. In the fifth example implementation, the semiconductor optical apparatus 570 may include a structure in which the semiconductor optical integrated device 1 according to the first example implementation may be mounted on a sub-mount 571. However, a semiconductor optical integrated device according to another example implementation may be mounted on the sub-mount 571.

The sub-mount 571 may have a structure obtained by metalizing a surface of a ceramic substrate. The sub-mount 571 has, on its top surface, a conductive pattern 572. The conductive pattern 572 may be connected to a reference potential (ground potential). The sub-mount 571 further has, on its top surface, transmission lines 574 and matching resistors 576. A capacitor 578 may be mounted on the conductive pattern 572. An electrode for connection to the sub-mount 571 may be formed on a rear surface of the semiconductor optical integrated device 1, and the electrode for the connection and the conductive pattern 572 may be connected to each other by solder.

An electrical signal for driving the laser section 10 may be input to the second laser-section electrode 18 via a wire. The first laser-section electrode 17 may be connected to the conductive pattern 572 via a wire 600. The capacitor 578 may be placed so as to electrically connect to the laser section 10 in parallel. The capacitor 578 may be omitted.

The transmission lines 574 form a pair of differential transmission lines. Differential electrical signals may be input to the transmission lines 574 from an outside. Here, a negative-phase signal may be input to the first modulation-section electrode 37 via a wire, and a positive-phase signal may be input to the second modulation-section electrode 38. The terms “positive phase” and “negative phase” here simply mean that the phases are reverse to each other. The matching resistors 576 may be wired so as to electrically connect to the modulation section 30 in parallel.

Owing to the inclusion of the high-resistance portion 40 in the waveguide section 20 of the semiconductor optical integrated device 1, electrical crosstalk between the laser section 10 and the modulation section 30 may be reduced. However, there may be a case in which leakage of an electrical signal is not completely preventable. When it is the case, an adverse effect of an electrical signal leaked from the modulation section 30 on operation of the laser section 10 may be reduced by using a short wire as the wire 600. The length of the wire 600 does not affect operation of the laser section 10 because the laser section 10 may be driven by a direct-current signal. However, in order to reduce the adverse effect of an electrical signal leaked from the modulation section 30, the length of the wire 600 is preferred to be 300 μm or less. A more preferred length of the wire 600 is 250 μm or less. Although an example in which the modulation section 30 is driven by differential drive is given here, the modulation section 30 may be driven by single-ended drive.

The present invention is not limited to just the embodiments described above. A case in which the substrate 2 is a semi-insulating semiconductor substrate is described in the embodiments, but a conductive substrate may be used. However, when a conductive substrate may be used, a semi-insulating semiconductor layer may be placed between the conductive substrate and the lower semiconductor layers. In the embodiments, a shape of the boundary between the first high-resistance portion and the second high-resistance portion in plan view is linear and parallel to the second direction D2, but is not limited thereto and may be a shape that is slanted relative to a straight line parallel to the second direction, or may be a shape that includes a curve. The width of each of the plurality of first high-resistance portions and the width of each of the plurality of second high-resistance portions in the first direction D1 may differ from each other. The description given above also takes, as an example, the semiconductor optical integrated device having a structure in which the laser section and the modulation section may be integrated. However, the present invention is not limited thereto, and the semiconductor optical integrated device may have a structure in which other optical function sections may be integrated. For example, the semiconductor optical integrated device may have a structure integrating a direct-modulation semiconductor laser section which generates a modulated optical signal and an optical amplification section which amplifies the modulated optical signal. In this case, a waveguide section may be placed between the direct-modulation semiconductor laser section and the optical amplification section. Further, the number of optical function sections integrated on one substrate is not limited to two. The effects of the present invention may be obtained as long as an isolation section for reducing electrical crosstalk between two optical function sections to which different electrical signals may be applied may be placed between the two optical function sections, and may include the high-resistance portion described above.

According to the present invention, in a semiconductor optical integrated device in which two optical function sections are integrated on one substrate, electrical crosstalk between the two optical function sections is reduced. Some implementations of the present invention achieve the above-mentioned reduction of electrical crosstalk by including an isolation section between the two optical function sections and giving the isolation section a high-resistance portion in which a plurality of semiconductor portions different from each other are alternatingly arranged in an optical axis direction. The different semiconductor portions forming the high-resistance portion include a first high-resistance portion and a second high-resistance portion. The first high-resistance portion and the second high-resistance portion differ from each other in one of dopant, material that serves as a base, and carrier concentration. The semiconductor optical integrated device is desired to include four or more, more preferably six or more semiconductor boundaries each of which is a boundary between the first high-resistance portion and the second high-resistance portion, between the two optical function sections. The high-resistance portion is placed between a lower semiconductor layer included in one of the two optical function sections and a lower semiconductor layer included in another of the two optical function sections. Desirably, the high-resistance portion is included in a lower semiconductor layer included in the isolation section, and takes up an 80% or more region of the lower semiconductor layer. In a direction perpendicular to the optical axis direction and to a normal line direction of the substrate, the lower semiconductor layer included in the isolation section is narrower in width than the lower semiconductor layers included in the two optical function sections. The two optical function sections are, for example, a laser section and a modulation section, but are not limited thereto. In a semiconductor optical apparatus in which a semiconductor optical integrated device integrating a laser section and a modulation section is mounted on a sub-mount, a wire connecting the laser section and a conductive pattern which connects to a reference potential to each other is preferred to have a length of 300 μm or less.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor optical integrated device, comprising:
a first optical function section;
an isolation section; and
a second optical function section,
the first optical function section, the isolation section, and the second optical function section being aligned in a first direction in the stated order,
the isolation section including a first high-resistance portion which is a semiconductor and a second high-resistance portion which is a semiconductor different from the first high-resistance portion,
the first high-resistance portion and the second high-resistance portion being alternatingly arranged in the first direction,
wherein the semiconductor optical integrated device includes semiconductor boundaries, the number of which is four or more, and each of which is a boundary between the first high-resistance portion and the second high-resistance portion.

2. The semiconductor optical integrated device according to claim 1, wherein the first high-resistance portion and the second high-resistance portion differ from each other in at least one of dopant, material that serves as a base, or carrier concentration.

3. The semiconductor optical integrated device according to claim 1,
wherein the first optical function section, the isolation section, and the second optical function section include a lower semiconductor layer common to one another,
wherein the lower semiconductor layer has a first conductivity type in the first optical function section and the second optical function section, and
wherein the lower semiconductor layer in the isolation section includes the first high-resistance portion and the second high-resistance portion.

4. The semiconductor optical integrated device according to claim 3, wherein the first high-resistance portion and the second high-resistance portion take up an 80% or more region of the lower semiconductor layer in the isolation section.

5. The semiconductor optical integrated device according to claim 3, wherein the first high-resistance portion and the second high-resistance portion each have one side edge that reaches corresponding one side edge of the semiconductor optical integrated device, in a second direction orthogonal to the first direction and to a normal line direction of the lower semiconductor layer.

6. The semiconductor optical integrated device according to claim 3, wherein the first high-resistance portion and the second high-resistance portion each have one side edge positioned inside corresponding one side edge of the semiconductor optical integrated device, in a second direction orthogonal to the first direction and to a normal line direction of the lower semiconductor layer.

7. The semiconductor optical integrated device according to claim 6,
wherein the lower semiconductor layer is a part of a mesa structure common to the first optical function section, the isolation section, and the second optical function section, and
wherein, in the second direction, the first high-resistance portion and the second high-resistance portion each have the same width as a width of the mesa structure.

8. The semiconductor optical integrated device according to claim 3, wherein the first high-resistance portion and the second high-resistance portion have bottom surfaces positioned above a top surface of a substrate, in a normal line direction of the lower semiconductor layer.

9. The semiconductor optical integrated device according to claim 3, wherein the lower semiconductor layer has a width narrower in the isolation section than in the first optical function section and the second optical function section, in a second direction orthogonal to the first direction and to a normal line direction of the lower semiconductor layer.

10. The semiconductor optical integrated device according to claim 9, wherein the second high-resistance portion has one side edge that reaches, in the second direction, corresponding one side edge of the lower semiconductor layer in the isolation section.

11. The semiconductor optical integrated device according to claim 9, wherein the second high-resistance portion has one side edge positioned, in the second direction, inside corresponding one side edge of the lower semiconductor layer in the isolation section.

12. The semiconductor optical integrated device according to claim 1, wherein the number of the semiconductor boundaries that are included is six or more.

13. The semiconductor optical integrated device according to claim 1,
wherein the first optical function section, the isolation section, and the second optical function section include a mesa structure common to one another, and
wherein the semiconductor optical integrated device further comprises, on each of two sides of the mesa structure, a buried layer in a second direction orthogonal to the first direction and to a normal line direction of a lower semiconductor layer.

14. The semiconductor optical integrated device according to claim 13, wherein the first high-resistance portion and the second high-resistance portion are placed only inside the mesa structure.

15. The semiconductor optical integrated device according to claim 13, wherein, in the second direction, the buried layer has a width narrower in the isolation section than in the first optical function section and the second optical function section.

16. The semiconductor optical integrated device according to claim 1, wherein, in the first optical function section and the second optical function section, an electrical signal applied to the first optical function section and an electrical signal applied to the second optical function section differ from each other.

17. A semiconductor optical apparatus, comprising:
the semiconductor optical integrated device of claim 1; and
a sub-mount on which the semiconductor optical integrated device is mounted.

18. The semiconductor optical apparatus according to claim 17,
wherein the first optical function section is a laser section including a laser-section electrode,
wherein the second optical function section is a modulation section,
wherein the sub-mount includes a conductive pattern connected to a reference potential,
wherein the semiconductor optical apparatus further comprises a wire that connects the laser-section electrode and the conductive pattern to each other, and
wherein the wire has a length of 300 μm or less.
